(19) United States
(12) Patent Application Publication
(10) Pub. No.: US 2024/0292692 A1
(43) Pub. Date: Aug. 29, 2024

(54) DISPLAY APPARATUS

(71) Applicant: LG Display Co., Ltd., Seoul (KR)

(72) Inventors: Jae-Yi CHOI, Paju-si (KR); Soo-Hong CHOI, Paju-si (KR); Hong-Jae SHIN, Paju-si (KR)

(73) Assignee: LG Display Co., Ltd., Seoul (KR)

(21) Appl. No.: 18/589,183

(22) Filed: Feb. 27, 2024

(30) Foreign Application Priority Data
Feb. 28, 2023 (KR) 10-2023-0027230

(51) Int. Cl. H10K 59/131; G09G 3/3225; G09G 3/3266

(52) U.S. Cl. CPC H10K 59/131; G09G 3/3225; G09G 3/3266; G09G 2300/0819; G09G 2300/0842

(57) ABSTRACT

A display apparatus includes a substrate including a display area having a subpixel and a non-display area surrounding the display area, a driving transistor provided at the subpixel, a light emitting diode provided at the subpixel and including a first electrode, an emitting layer, and a second electrode, and a gate driving unit provided in the non-display area, wherein the gate driving unit includes a line portion including at least one signal line and a stage portion including at least one stage, wherein the stage is connected to the signal line or a gate line of the display area through a connection line and a connection pattern, and wherein the connection pattern is provided of a same material and on a same layer as the first electrode.

### CROSS-REFERENCE TO RELATED APPLICATION

The present application claims priority to Korean Patent Application No. 10-2023-0027230 filed in the Republic of Korea on Feb. 28, 2023, the entire contents of which are hereby expressly incorporated by reference into the present application.

### TECHNICAL FIELD

The present disclosure relates to a display apparatus, and more particularly, to a display apparatus including a gate driving unit provided on a substrate.

### DISCUSSION OF THE RELATED ART

Recently, with the advent of an information-oriented society, the interest in information displays for processing and displaying a massive amount of information and the demand for portable information media have increased. As such, a display field has rapidly advanced. Thus, various light and thin flat panel display devices have been developed and highlighted.

Among the various flat panel display devices, an organic light emitting diode (OLED) display apparatus is an emissive type device that does not include a backlight unit used in a non-emissive type device such as a liquid crystal display (LCD) apparatus. As a result, the OLED display apparatus has advantages in a viewing angle, a contrast ratio and a power consumption to be applied to various fields.

The OLED display apparatus includes a plurality of subpixels in a display area, and each subpixel receives signals from a gate driving unit and a data driving unit to implement an image.

### SUMMARY

Recently, in the organic light emitting diode display apparatus, the gate driving unit may be provided as a gate in panel (GIP) type in a non-display area, thereby reducing manufacturing costs and processes.

However, static electricity may occur during the manufacturing processes of the organic light emitting diode display apparatus. When this static electricity flows into the gate driving unit, it may cause damage to the gate driving unit, which includes a plurality of elements, requiring a separate repair process. If repair is not possible, the organic light emitting diode display apparatus must be discarded, thereby increasing the manufacturing processes and costs.

Accordingly, embodiments of the present disclosure are directed to a display apparatus that substantially obviates one or more of the problems due to limitations and disadvantages of the related art.

An aspect of the present disclosure is to provide a display apparatus capable of preventing static electricity from flowing into a gate driving unit during manufacturing processes.

Another aspect of the present disclosure is to provide a display apparatus capable of reducing manufacturing processes and costs.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the present disclosure, as embodied and broadly described herein, a display apparatus comprises a substrate including a display area having a subpixel and a non-display area surrounding the display area, a driving transistor provided at the subpixel, a light emitting diode provided at the subpixel and including a first electrode, an emitting layer, and a second electrode, and a gate driving unit provided in the non-display area, wherein the gate driving unit includes a line portion including at least one signal line and a stage portion including at least one stage, wherein the stage is connected to the signal line or a gate line of the display area through a connection line and a connection pattern, and wherein the connection pattern is provided of a same material and on a same layer as the first electrode.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate embodiments of the disclosure and together with the description serve to explain various principles of the present disclosure. In the drawings:

FIG. 1 is a view showing a display apparatus according to an embodiment of the present disclosure;

FIG. 2 is block diagram showing first and second gate driving units and a display panel of a display apparatus according to an embodiment of the present disclosure;

FIG. 3 is a circuit diagram showing a subpixel of a display apparatus according to an embodiment of the present disclosure;

FIG. 4 is a circuit diagram showing a subpixel of a 3TIC structure of a display apparatus according to an embodiment of the present disclosure;

FIG. 5 is a cross-sectional view showing a subpixel of a display apparatus according to an embodiment of the present disclosure;

FIG. 6 is a plan view schematically illustrating a display panel of an organic light emitting diode display apparatus according to an embodiment of the present disclosure;

FIG. 7 is a plan view schematically enlarging the area A1 of FIG. 6;

FIG. 8 is a plan view schematically illustrating a transistor of a stage of FIG. 6;

FIG. 9 is a cross-sectional view corresponding to line I-I′ of FIG. 6;

FIG. 10 is a plan view schematically illustrating a display panel of an organic light emitting diode display apparatus according to another embodiment of the present disclosure;

FIG. 11 is a plan view schematically illustrating a transistor of a stage of FIG. 10; and

FIG. 12 is a cross-sectional view corresponding to line II-II′ of FIG. 10.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display apparatus” may include a display device in a narrow sense such as liquid crystal module (LCM), an organic light emitting diode (OLED) module and a quantum dot (QD) module including a display panel and a driving unit for driving the display panel. In addition, the term “display apparatus” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display apparatus of the present disclosure may include an applied product or a set device of a final user's device including the LCM, the OLED module and the QD module as well as a display apparatus in a narrow sense such as the LCM, the OLED module and the QD module.

According to circumstances, the LCM, the OLED module and the QD module having a display panel and a driving unit may be expressed as “a display apparatus”, and an electronic apparatus of a complete product including the LCM, the OLED module and the QD module may be expressed as “a set device.” For example, a display apparatus in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display apparatus of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of moisture or oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display apparatus according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

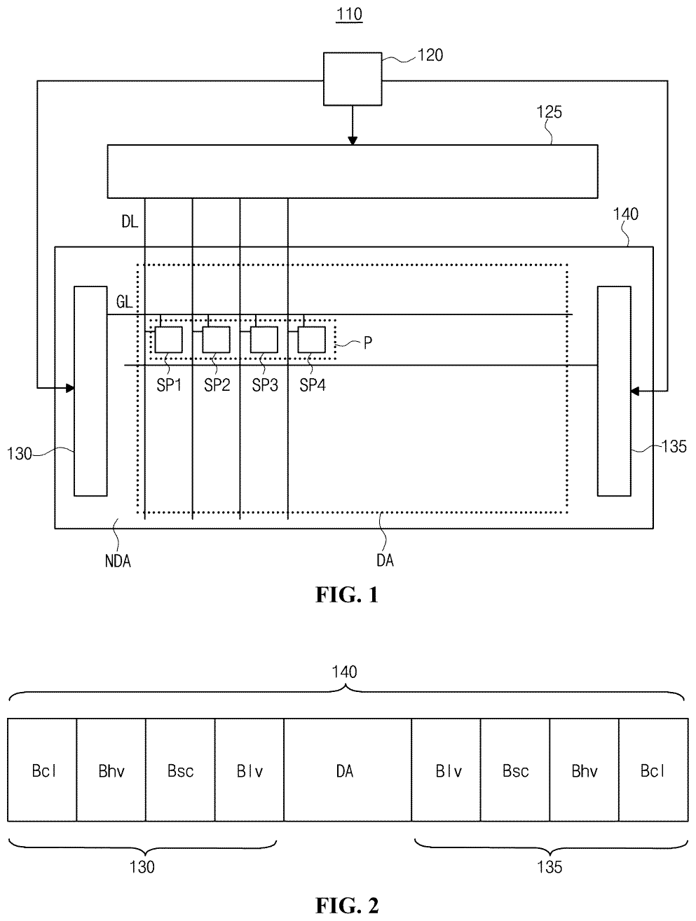

FIG. 1 is a view showing a display apparatus according to an embodiment of the present disclosure. The display apparatus may be an organic light emitting diode (OLED) display apparatus.

In FIG. 1, a display apparatus 110 according to an embodiment of the present disclosure includes a timing controlling unit 120, a data driving unit 125, first and second gate driving units 130 and 135 and a display panel 140.

The timing controlling unit 120 (e.g., a circuit) generates an image data, a data control signal and a gate control signal using an image signal and a plurality of timing signals including a data enable signal, a horizontal synchronization signal, a vertical synchronization signal and a clock signal transmitted from an external system such as a graphic card or a television system. The image data and the data control signal are transmitted to the data driving unit 125, and the gate control signal is transmitted to the first and second gate driving units 130 and 135.

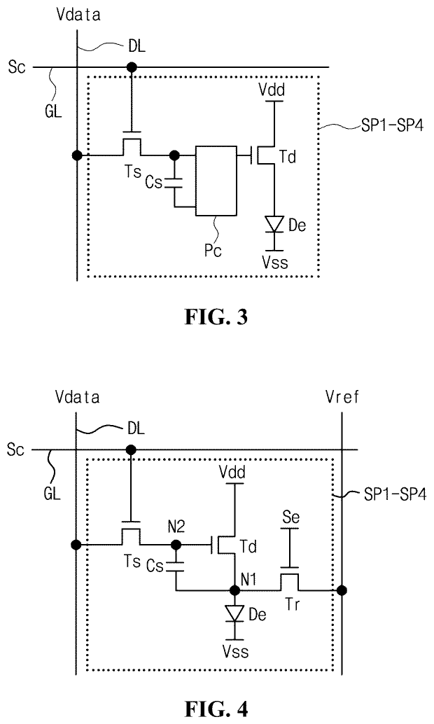

The data driving unit 125 (e.g., a circuit) generates a data signal (a data voltage) Vdata (of FIG. 3) using the data control signal and the image data transmitted from the timing controlling unit 120 and transmits the data signal to a data line DL of the display panel 140.

The first and second gate driving units 130 and 135 (e.g., circuits) generate a gate signal (a gate voltage) using the gate control signal transmitted from the timing controlling unit 120 and applies the gate signal to a gate line GL of the display panel 140. For example, the gate signal may include a scan signal Sc (of FIG. 4), a sensing signal Se (of FIG. 4) and an emission signal.

The first and second gate driving units 130 and 135 may be a gate in panel (GIP) type formed in a non-display area NDA of a substrate of the display panel 140 having the gate line GL, the data line DL and a pixel P.

Although the first and second gate driving units 130 and 135 are disposed in both side portions of the display panel 140 in the embodiment of FIG. 1, one gate driving unit may be disposed in one side portion of the display panel 140 in another embodiment.

The display panel 140 includes a display area DA at a central portion thereof and a non-display area NDA adjacent to and surrounding the display area DA. The display panel 140 displays an image using the gate signal and the data signal Vdata. For displaying an image, the display panel 140 includes a plurality of pixels P, a plurality of gate lines GL and a plurality of data lines DL in the display area DA.

Each of the plurality of pixels P includes first, second, third and fourth subpixels SP1, SP2, SP3 and SP4, and the gate line GL and the data line DL cross each other to define the first, second, third and fourth subpixels SP1, SP2, SP3 and SP4. Each of the first, second, third and fourth subpixels SP1, SP2, SP3 and SP4 is connected to the gate line GL and the data line DL. For example, the first, second, third and fourth subpixels SP1, SP2, SP3 and SP4 may correspond to red, green, blue and white, respectively.

When the display apparatus 110 is an OLED display apparatus, each of the first, second, third and fourth subpixels SP1, SP2, SP3 and SP4 may include a plurality of transistors such as a switching transistor Ts (of FIG. 4), a driving transistor Td (of FIG. 4) and a reference transistor Tr (of FIG. 4), a storage capacitor Cs (of FIG. 4) and a light emitting diode De (of FIG. 4).

A structure and an operation of the first and second gate driving units 130 and 135 and the first, second, third and fourth subpixels SP1, SP2, SP3 and SP4 of the display apparatus 110 will be illustrated with reference to a drawing.

FIG. 2 is block diagram showing first and second gate driving units and a display panel of a display apparatus according to an embodiment of the present disclosure, and FIG. 3 is a circuit diagram showing a subpixel of a display apparatus according to an embodiment of the present disclosure. The display apparatus 110 may be an organic light emitting diode (OLED) display apparatus.

In FIG. 2, each of the first and second gate driving units 130 and 135 of the display apparatus 110 according to an embodiment of the present disclosure includes a clock signal block Bcl (e.g., a circuit), a high-level voltage block Bhv (e.g., a circuit), a stage circuit block Bsc (e.g., a circuit) and a low-level voltage block Blv (e.g., a circuit), and the display area DA is disposed between the first and second gate driving units 130 and 135.

In another embodiment, the disposition structure of the clock signal block Bcl, the high-level voltage block Bhv, the stage circuit block Bsc and the low-level voltage block Blv in the first and second gate driving units 130 and 135 may be variously changed.

Each of the first and second gate driving units 130 and 135 may include a shift register including a plurality of stages connected to each other in a cascade type.

The clock signal block Bcl includes a plurality of clock lines transmitting a clock signal used in the stage circuit block Bsc.

For example, the clock signal may include a carry clock transmitted between one stage and another stage of the shift register, a scan clock used for generation of the scan signal Sc of the gate signal supplied to the display area DA of the display panel 140 and a sensing clock used for generation of the sensing signal Se of the gate signal supplied to the display area DA of the display panel 140.

The clock signal block Bcl may include a carry clock block including the clock line transmitting the carry clock, a scan clock block including the clock line transmitting the scan clock and a sensing clock block including the clock line transmitting the sensing clock.

The high-level voltage block Bhv includes a plurality of power lines transmitting the high-level voltage and the control signal of the first and second gate driving units 130 and 135.

For example, the high-level voltage of the first and second gate driving units 130 and 135 may include a high-level voltage for a shift register and a high-level voltage for an inverter of each stage, and the control signal of the first and second gate driving units 130 and 135 may include a start signal corresponding to an operation start of a first stage, a reset signal corresponding to an operation end of a last stage and a real time signal used for generation of a compensation signal in an operation for a real time compensation.

The stage circuit block Bsc as one stage of the shift register includes a plurality of transistors and a plurality of capacitors, and generates and outputs the gate signal including the carry signal, the scan signal Sc and the sensing signal Se. The carry signal is transmitted to the other stage, and the scan signal Sc and the sensing signal Se are transmitted to the display area DA.

For example, the stage circuit block Bsc may include a compensation block for an operation of a real time operation, a carry block including a line transmitting the carry signal to the other stage, a logic block substantially generating a plurality of output signals and a buffer block outputting the scan signal Sc and the sensing signal Se of the gate signal supplied to the display area DA of the display panel 140.

The stage circuit block Bsc may include a plurality of transistors and a plurality of capacitors.

The low-level voltage block Blv includes the plurality of power lines transmitting the low-level voltage of the first and second gate driving units 130 and 135.

In the first and second gate driving units 130 and 135, the stage block Bsc generates the carry signal, the scan signal Sc and the sensing signal Se using the carry clock, the scan clock and the sensing clock transmitted from the clock signal block Bcl. The carry signal is transmitted to the other stage circuit block Bsc, and the scan signal Sc and the sensing signal Se are transmitted to each subpixel SP1, SP2, SP3 and SP4 of the display area DA.

In FIG. 3, each of the first, second, third and fourth subpixels SP1, SP2, SP3 and SP4 of the display panel 140 of the display apparatus 110 according to an embodiment of the present disclosure includes a switching transistor Ts, a driving transistor Td, a compensation part Pc, a storage capacitor Cs and a light emitting diode De. The switching transistor Ts and the driving transistor Td may be an oxide semiconductor thin film transistor or a low temperature polycrystalline silicon thin film transistor.

The switching transistor Ts is switched according to the scan signal Sc of the gate signal. A gate electrode of the switching transistor Ts is connected to the gate line GL supplying the scan signal Sc, a source electrode of the switching transistor Ts is connected to a first capacitor electrode of the storage capacitor Cs and the compensation part Pc, and a drain electrode of the switching transistor Ts is connected to the data line DL supplying the data signal Vdata.

The driving transistor Td is switched according to a voltage of the compensation part Pc. A gate electrode of the driving transistor Td is connected to the compensation part Pc, a source electrode of the driving transistor Td is connected to an anode of the light emitting diode De, and a drain electrode of the driving transistor Td is connected to the high-level voltage Vdd.

The compensation part Pc is connected among the switching transistor Ts, the driving transistor Td and the storage capacitor Cs and compensates a variation of the threshold voltage Vth of the driving transistor Td.

The storage capacitor Cs stores the data signal Vdata. A first capacitor electrode of the storage capacitor Cs is connected to the source electrode of the switching transistor Ts and the compensation part Pc, and a second capacitor electrode of the storage capacitor Cs is connected to the compensation part Pc.

The light emitting diode De is connected between the driving transistor Td and the low-level voltage Vss and emits a light of a luminance proportional to a current of the driving transistor Td. An anode of the light emitting diode De is connected to the source electrode of the driving transistor Td, and a cathode of the light emitting diode De is connected to the low-level voltage Vss.

The data signal Vdata is supplied from the data driving unit 125 to each subpixel SP1, SP2, SP3 and SP4 of the display panel 140, and the scan signal Sc of the gate signal is supplied from the first and second gate driving units 130 and 135 to each subpixel SP1, SP2, SP3 and SP4 of the display panel 140.

Each of the first, second, third and fourth subpixels SP1, SP2, SP3 and SP4 may have one of 3TIC structure including three transistors and one capacitor, 6TIC structure including six transistors and one capacitor, 7T1C structure including seven transistors and one capacitor and 8TIC structure including eight transistors and one capacitor. However, embodiments of the present disclosure are not limited thereto. Alternatively, each of the first, second, third and fourth subpixels SP1, SP2, SP3 and SP4 may have one of 4T3C structure, 5T2C structure, 6T2C structure, and 7T2C structure including two capacitors.

A 3TIC structure of each subpixel SP1, SP2, SP3 and SP4 will be illustrated with reference to a drawing.

FIG. 4 is a circuit diagram showing a subpixel of a 3TIC structure of a display apparatus according to an embodiment of the present disclosure.

In FIG. 4, each of the first, second, third and fourth subpixels SP1, SP2, SP3 and SP4 of the display panel 140 of the display apparatus 110 according to an embodiment of the present disclosure includes a switching transistor Ts, a driving transistor Td, a reference transistor Tr, a storage capacitor Cs and a light emitting diode De. The switching transistor Ts, the driving transistor Td and the reference transistor Tr may be an oxide semiconductor thin film transistor or a low temperature polycrystalline silicon thin film transistor.

The switching transistor Ts is switched according to a scan signal Sc of the gate signal. A gate electrode of the switching transistor Ts is connected to the gate line GL supplying the scan signal Sc, a source electrode of the switching transistor Ts is connected to a first capacitor electrode of the storage capacitor Cs and a gate electrode of the driving transistor Td, and a drain electrode of the switching transistor Ts is connected to the data line DL supplying the data signal Vdata.

The driving transistor Td is switched according to a voltage of the first capacitor electrode of the storage capacitor Cs. A gate electrode of the driving transistor is connected to the source electrode of the switching transistor Ts and the first capacitor electrode of the storage capacitor Cs, a source electrode of the driving transistor Td is connected to a second capacitor electrode of the storage capacitor Cs, an anode of the light emitting diode De and a source electrode of the reference transistor Tr, and a drain electrode of the driving transistor Td is connected to the high-level voltage Vdd.

The reference transistor Tr is switched according to a sensing signal Se of the gate signal. A gate electrode of the reference transistor Tr is connected to a gate line supplying the sensing signal Se, a source electrode of the reference transistor Tr is connected to the source electrode of the driving transistor Td, the second capacitor electrode of the storage capacitor Cs, and the anode of the light emitting diode De, and a drain electrode of the reference transistor Tr is connected to the reference signal Vref.

The storage capacitor Cs stores the data signal Vdata compensated with a threshold voltage Vth of the driving transistor Td. The first capacitor electrode of the storage capacitor Cs is connected to the source electrode of the switching transistor Ts and the gate electrode of the driving transistor Td, and the second capacitor electrode of the storage capacitor Cs is connected to the source electrode of the driving transistor Td, the source electrode of the reference transistor Tr and the anode of the light emitting diode De.

The light emitting diode De is connected between the driving transistor Td and the low-level voltage Vss and emits a light of a luminance proportional to a current of the driving transistor Td. The anode of the light emitting diode De is connected to the source electrode of the driving transistor Td, the second capacitor electrode of the storage capacitor Cs and the source electrode of the reference transistor Tr, and a cathode of the light emitting diode De is connected to the low-level voltage Vss.

The data signal Vdata and the reference signal Vref are supplied from the data driving unit 125 to each subpixel SP1 to SP4 of the display panel 140, and the scan signal Sc and the sensing signal Se of the gate signal are supplied from the first and second gate driving units 130 and 135 to each subpixel SP1 to SP4 of the display panel 140.

The source electrode of the driving transistor Td, the source electrode of the reference transistor Tr, the second capacitor electrode of the storage capacitor Cs and the anode of the light emitting diode De are connected to each other to constitute a first node N1, and the gate electrode of the driving transistor Td, the source electrode of the switching transistor Ts and the first capacitor electrode of the storage capacitor Cs are connected to each other to constitute a second node N2.

In the display apparatus 110, during an initialization period where the reference transistor Tr is turned on, the reference signal Vref is supplied to the first node N1 and the first and second nodes N1 and N2 are initialized. During a writing period where the switching transistor Ts is turned on and off, the data signal Vdata is applied to the second node N2 and the threshold voltage of the driving transistor Td is stored in the storage capacitor Cs. During a sensing period where the reference transistor Tr is turned on again, the data driving unit 125 detects the threshold voltage of the driving transistor Td stored in the storage capacitor Cs and transmits the threshold voltage to the timing controlling unit 120.

Next, the timing controlling unit 120 modifies the data signal Vdata to generate a compensated data signal where the threshold voltage is compensated and supply the compensated data signal to each subpixel SP1 to SP4 through the data driving unit 125. During an emission period where the switching transistor Ts is turned on, a current corresponding to the compensated data signal is supplied to the light emitting diode De through the driving transistor Td and the light emitting diode De emits a light.

A cross-sectional structure of each subpixel will be illustrated with reference to a drawing.

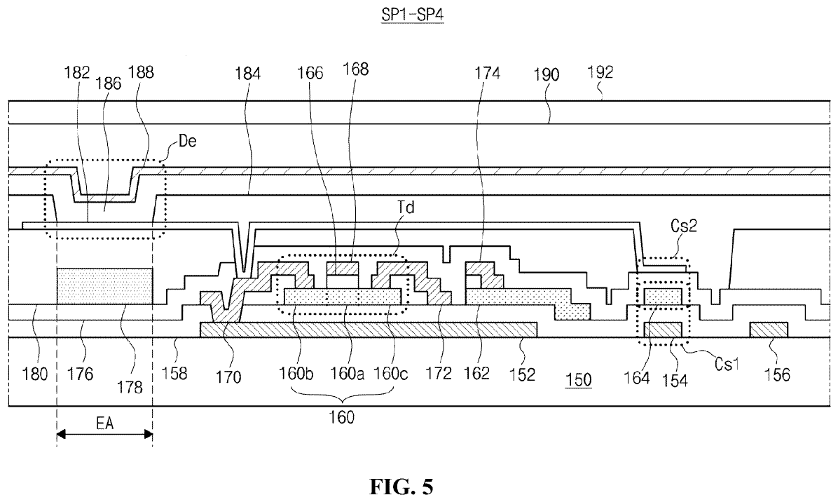

FIG. 5 is a cross-sectional view showing a subpixel of a display apparatus according to an embodiment of the present disclosure.

In FIG. 5, each subpixel SP1 to SP4 of the display apparatus 110 according to an embodiment of the present disclosure includes the driving transistor Td and the light emitting diode De.

A light shielding layer 152, a first capacitor pattern 154 and a data line 156 are disposed on a substrate 150.

The substrate 150 may include glass. However, embodiments of the present disclosure are not limited thereto. Alternatively, the substrate 150 may include a multiple layer where an organic layer and an inorganic layer are alternately laminated. For example, the substrate 150 may include an organic insulating material layer such as polyimide (PI) and an inorganic insulating material layer such as silicon oxide (SiO₂) alternately laminated.

The light shielding layer 152, the first capacitor pattern 154 and the data line 156 may have the same layer and the same material as each other through a single mask process. The light shielding layer 152, the first capacitor pattern 154 and the data line 156 may include a metallic material.

For example, the light shielding layer 152, the first capacitor pattern 154 and the data line 156 may have a single layer or multiple layers including one of molybdenum (Mo), aluminum (Al), chromium (Cr), gold (Au), titanium (Ti), nickel (Ni), neodymium (Nd), copper (Cu) and an alloy thereof.

A buffer layer 158 is disposed on the light shielding layer 152, the first capacitor pattern 154 and the data line 156 over the entire substrate 150. The buffer layer 158 may block moisture penetrable from an exterior. For example, the buffer layer 158 may have a multiple layer of an inorganic material such as silicon oxide (SiOx) or silicon nitride (SiNx).

An active layer 160 and a semiconductor layer 162 are disposed on the buffer layer 158 corresponding to the light shielding layer 152, and a second capacitor pattern 164 is disposed on the buffer layer 158 corresponding to the first capacitor pattern 154.

The active layer 160, the semiconductor layer 162 and the second capacitor pattern 164 may have the same layer and the same material as each other through a single mask process. The active layer 160, the semiconductor layer 162 and the second capacitor pattern 164 may include polycrystalline silicon or oxide semiconductor material.

The active layer 160 may have a channel region 160a at a central portion thereof and source and drain regions 160b and 160c at both side portions of the channel region 160a. The channel region 160a may include an intrinsic semiconductor material without an impurity, and the source and drain regions 160b and 160c may include an impurity doped semiconductor material. In this case, the active layer 160 may include polycrystalline silicon.

However, embodiments of the present disclosure are not limited thereto. Alternatively, when the active layer 160 includes oxide semiconductor material, the channel region 160a, the source region 160b, and the drain region 160c may include an intrinsic semiconductor material without an impurity.

The first capacitor pattern 154, the buffer layer 158 and the second capacitor pattern 164 constitute a first storage capacitor Cs1.

A patterned gate insulating layer 166 is disposed on the channel region 160a, the source region 160b and the drain region 160c of the active layer 160 and the semiconductor layer 162. The gate insulating layer 166 may have a single layer or a multiple layer of an inorganic insulating material such as silicon oxide (SiO₂) and silicon nitride (SiNx).

A gate electrode 168, a source electrode 170 and a drain electrode 172 are disposed on the gate insulating layer 166 corresponding to the channel region 160a, the source region 160b and the drain region 160c, respectively, of the active layer 160, and a gate line 174 is disposed on the gate insulating layer 166 corresponding to the semiconductor layer 162.

The gate electrode 168, the source electrode 170, the drain electrode 172 and the gate line 174 may have the same layer and the same material as each other through a single mask process. The gate electrode 168, the source electrode 170, the drain electrode 172 and the gate line 174 may include a metallic material.

For example, the gate electrode 168, the source electrode 170, the drain electrode 172 and the gate line 174 may have a single layer or multiple layers including one of molybdenum (Mo), aluminum (Al), chromium (Cr), gold (Au), titanium (Ti), nickel (Ni), neodymium (Nd), copper (Cu) and an alloy thereof.

The gate electrode 168 does not contact the channel region 160a of the active layer 160. On the other hand, the source electrode 170 contacts the light shielding layer 152 through a contact hole of the buffer layer 158 and the source region 160b of the active layer 160 through a side surface of the gate insulating layer 166. Further, the drain electrode 172 contacts the drain region 160c of the active layer 160 through the side surface of the gate insulating layer 166, and the gate line 174 contacts the semiconductor layer 162 through the side surface of the gate insulating layer 166.

In another embodiment, an additional metal layer may be disposed between the active layer 160 and the source electrode 170 and between the active layer 160 and the drain electrode 172. The metal layer may be formed simultaneously with the active layer 160 through a photolithographic process using a half transmissive mask.

The active layer 160, the gate insulating layer 166, the gate electrode 168, the source electrode 170 and the drain electrode 172 constitute the driving transistor Td.

In the embodiment of the present disclosure, the source and drain electrodes 170 and 172 are described as being formed of the same material and on the same layer as the gate electrode 168, but embodiments of the present disclosure are not limited thereto.

In other embodiments, the source and drain electrodes 170 and 172 may be formed of the same material as and on a different layer from the gate electrode 168 or formed of a different material and on a different layer from the gate electrode 168. In this case, the data line 156 may be formed of the same material and on the same layer as the source and drain electrodes 170 and 172.

A passivation layer 176 is disposed on the gate electrode 168, the source electrode 170, the drain electrode 172, the gate line 174 and the second capacitor pattern 164 over the entire substrate 150. The passivation layer 176 may have a single layer or a multiple layer of an inorganic insulating material such as silicon oxide (SiOx) and silicon nitride (SiNx).

A color filter layer 178 is disposed in an emission area EA on the passivation layer 176. For example, the color filter layer 178 of the first, second, third and fourth subpixels SP1, SP2, SP3 and SP4 may correspond to red, green, blue and white colors, respectively.

An overcoat layer 180 is disposed on the color filter layer 178 over the entire substrate 150. The overcoat layer 180 may include an organic insulating material such as polyimide (PI) and acrylic resin.

A first electrode 182 is disposed on the overcoat layer 180 and is connected to the source electrode 170 through a contact hole in the overcoat layer 180 and the passivation layer 176. The first electrode 182 may be an anode of a multiple layer including a transparent conductive material.

For example, the transparent conductive material may include a material having a relatively high work function such as indium tin oxide (ITO) and indium zinc oxide (IZO).

The first electrode 182 extends from the emission area EA to overlap the second capacitor pattern 164. The second capacitor pattern 164, the passivation layer 176 and the first electrode 182 constitute a second storage capacitor Cs2.

The first and second storage capacitors Cs1 and Cs2 are connected to each other in parallel to constitute the storage capacitor Cs (of FIG. 3).

A bank layer 184 is disposed on the first electrode 182 to cover an edge portion of the first electrode 182. The bank layer 184 has an opening exposing a central portion of the first electrode 182, and the opening of the bank layer 184 corresponds to the emission area EA.

For example, the bank layer 184 may include an opaque material (e.g. black material) to prevent light interference between the adjacent subpixels SP1 to SP4. The bank layer 184 may include a shielding material of at least one of a color pigment, an organic black and a carbon.

However, embodiments of the present disclosure are not limited thereto. Alternatively, the bank layer 184 may include a transparent material. For example, the bank layer 184 may include at least one material of an inorganic insulating material such as silicon oxide (SiOx) and silicon nitride (SiNx) or an organic insulating material such as benzocyclobutene (BCB), acrylic resin, epoxy resin, phenolic resin, polyamide resin, or polyimide resin.

Although not shown, a spacer may be disposed on the bank layer 184.

An emitting layer 186 is disposed on the bank layer 184 and the first electrode 182 exposed through the opening of the bank layer 184. The emitting layer 186 may include a hole relating layer, an organic emitting layer and an electron relating layer sequentially or reversely laminated.

For example, the emitting layer 186 may include a hole injecting layer, a hole transporting layer, an emitting material layer, an electron transporting layer and an electron injecting layer.

A second electrode 188 is disposed on the emitting layer 186 over the entire substrate 150. The second electrode 188 may be a cathode of a multiple layer including an opaque conductive material having a relatively high reflection efficiency.

For example, the opaque conductive material may include a material having a relatively low work function such as aluminum (Al), silver (Ag), copper (Cu), lead (Pb), molybdenum (Mo), titanium (Ti) and an alloy thereof.

The first electrode 182, the emitting layer 186 and the second electrode 188 constitute the light emitting diode De.

Although the display apparatus 110 has a bottom emission type where the first electrode 182 includes a transparent material and the second electrode 188 has an opaque material having a relatively high reflectance in an embodiment of FIG. 5, the display apparatus 110 may have a top emission type where the first electrode 182 includes an opaque material having a relatively high reflectance and the second electrode 188 includes a transparent or semi-transparent material and the color filter layer 178 is disposed on the second electrode 188 in another embodiment.

A first encapsulating layer 190 and a second encapsulating layer 192 are sequentially disposed on the second electrode 188 over the entire substrate 150 as an encapsulation member. The first encapsulating layer 190 and the second encapsulating layer 192 may prevent moisture or oxygen of an exterior from permeating the light emitting diode De.

For example, the first encapsulating layer 190 may include a non-photosensitive organic insulating material such as acrylic resin, epoxy resin, phenolic resin, polyamide resin, polyimide resin, polyethylene and silicon oxycarbon (SiOC) or a photosensitive organic insulating material such as photoacryl. Alternatively, the first encapsulating layer 190 may include an inorganic insulating material such as silicon nitride (SiNx), silicon oxide (SiOx), or aluminum oxide (AlyOz) or may have a structure where at least one inorganic insulating material and at least one organic insulating material are stacked.

The second encapsulating layer 192 may include a metallic material. For example, the second encapsulating layer 192 may include iron (Fe), nickel (Ni), titanium (Ti), molybdenum (Mo), copper (Cu), aluminum (Al), silver (Ag), chromium (Cr), gold (Au), neodymium (Nd), or alloys thereof, but embodiments of the present disclosure are not limited thereto.

Alternatively, when the display apparatus 110 may have a top emission type, the second encapsulating layer 192 may include a transparent insulating material. For example, the second encapsulating layer 192 may include glass.

In the organic light emitting diode display apparatus 110, after forming components of the stages of the first and second gate driving units 130 and 135 by electrically separating them from signal lines, the components of the stages are connected to the signal lines when forming the first electrode 182. This will be described with reference to the drawings.

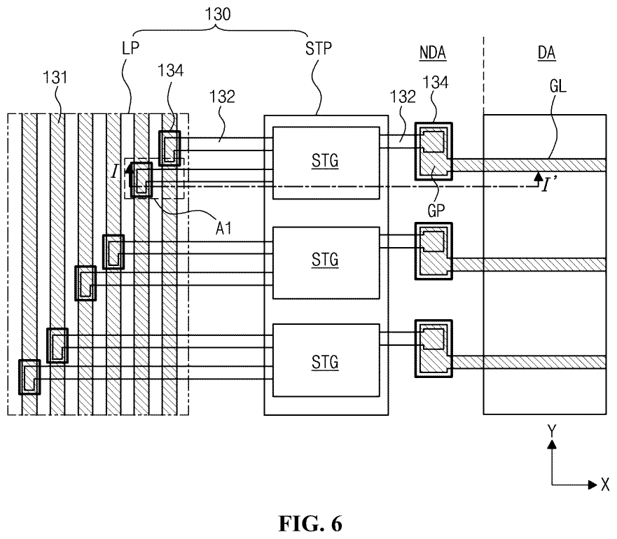

FIG. 6 is a plan view schematically illustrating a display panel of an organic light emitting diode display apparatus according to an embodiment of the present disclosure and shows a gate driving unit and a display area.

In FIG. 6, the display panel 140 of the organic light emitting diode display apparatus 110 according to the embodiment of the present disclosure includes the display area DA at a central portion thereof and the non-display area NDA surrounding the display area DA on the substrate 150.

The plurality of gate lines GL is provided in the display area DA and extends in a first direction, which is an X direction. A gate pad GP is provided at one end of each gate line GL, and the gate pad GP is disposed in the non-display area NDA.

In the figure, the first and second gate driving units 130 and 135 are disposed in the non-display area NDA located at left and right sides of the display area DA, respectively.

In the embodiment of the present disclosure, the first and second gate driving units 130 and 135 and the corresponding left and right configurations of the non-display area NDA of the display panel 140 are substantially the same as each other. Accordingly, for convenience of description, the following description will be made based on the first gate driving unit 130 and the corresponding left configuration of the non-display area NDA, and the first gate driving unit 130 will be referred to as the gate driving unit 130. Therefore, the features mentioned below for the gate driving unit 130 and the corresponding configuration equally apply to the first and second gate driving units 130 and 135 and the corresponding configurations.

The gate driving unit 130 includes a stage portion STP including a plurality of stages STG and a line portion LP including a plurality of signal lines 131. The stage portion STP is disposed between the line portion LP and the display area DA. Here, the plurality of signal lines 131 may extend in a second direction, which is a Y direction.

The stage portion STP may correspond to the stage circuit block Bsc of FIG. 2, and the line portion LP may correspond to the clock signal block Bcl and the high-level voltage block Bhv of FIG. 2. The stages STG of the stage portion STP may include a plurality of transistors and a plurality of capacitors and output the gate signal. The signal lines 131 of the line portion LP may transmit a scan clock, a carry clock, a gate high-level voltage, a start signal, a reset signal, or a real time signal.

Each stage STG is electrically connected to at least one signal line 131 and at least one gate line GL. Here, the signal line 131 and the gate line GL may be provided of the same material and on the same layer.

Specifically, the stage STG is electrically connected to the signal line 131 and the gate line GL through a connection line 132 and a connection pattern 134, respectively. In this case, the connection line 132 and the connection pattern 134 may be electrically connected to the gate line GL through the gate pad GP.

The connection line 132 may extend in the first direction and may overlap the signal line 131 or the gate pad GP. The connection line 132 may be directly connected to a gate layer or a source/drain layer provided in the stage STG.

The connection pattern 134 may overlap the signal line 131 and the connection line 132 or may overlap the gate pad GP and the connection line 132.

The connection line 132 and the connection pattern 134 are provided of different materials and on different layers from each other. In addition, the connection line 132 and the connection pattern 134 may be disposed on different layers from the signal line 131 and the gate line GL.

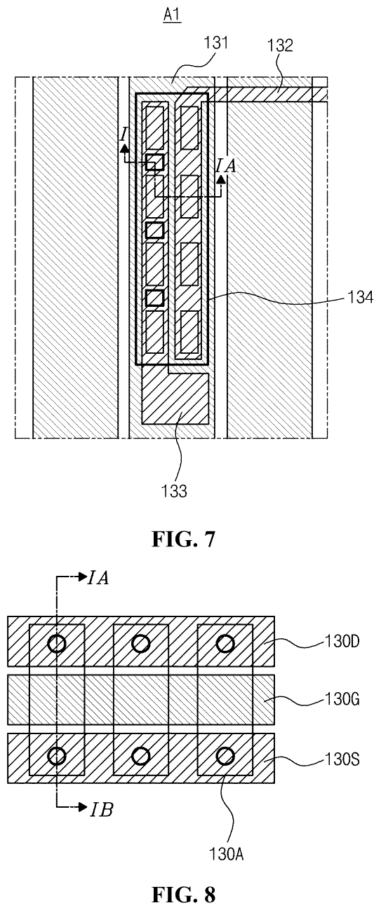

Hereinafter, plan and cross-sectional configurations of the display panel of FIG. 6 will be described in detail with reference to FIGS. 7 to 9.

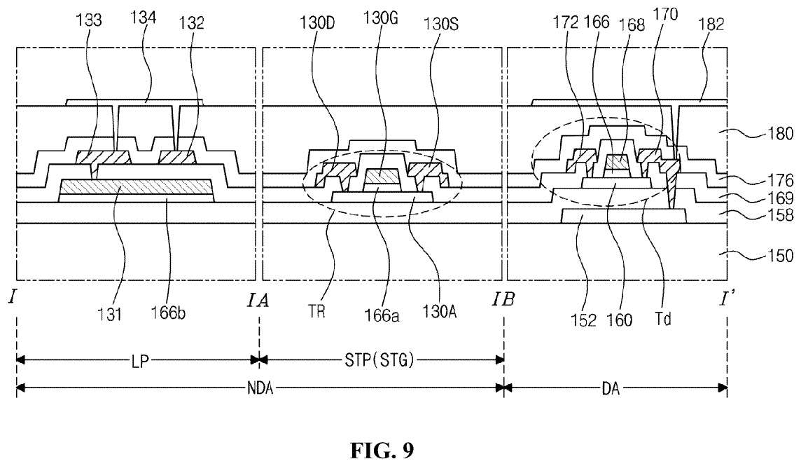

FIG. 7 is a plan view schematically enlarging the area A1 of FIG. 6, FIG. 8 is a plan view schematically illustrating a transistor of a stage of FIG. 6, and FIG. 9 is a cross-sectional view corresponding to line I-I′ of FIG. 6. FIG. 9 also shows a cross-sectional configuration corresponding to line I-IA of FIG. 7 and a cross-sectional configuration corresponding to the line IA-IB of FIG. 8.

Here, the structure of the display area DA has substantially the same configuration as that described in FIG. 5 except for the source and drain electrodes 170 and 172 provided on a different layer from the gate electrode 168. The same or similar parts as those of FIG. 5 will be designated by the same or similar references, and explanation for the same parts will be omitted or shortened.

In FIGS. 7, 8, and 9, the light shielding layer 15, the driving transistor Td, the light emitting diode De are provided in the display area DA on the substrate 150. The transistor TR, the signal line 131, the connection line 132, and the connection pattern 134 are provided in the non-display area NDA on the substrate 150. The transistor TR is disposed in each stage STG of the stage portion STP, and the signal line 131 is disposed in the line portion LP.

Here, the driving transistor Td includes the gate electrode 168, the active layer 160, the source electrode 170, and the drain electrode 172, and the light emitting diode De includes the first electrode 182, the emitting layer 186, and the second electrode 188.

The transistor TR includes a gate 130G, an active pattern 130A, a source 130S, and a drain 130D.

Specifically, the light shielding layer 152 is provided on the substrate 150 as a first conductive layer, and the buffer layer 185 is provided on the light shielding layer 152. The buffer layer 158 is disposed substantially over an entire surface of the substrate 150.

The active layer 160 is provided on the buffer layer 158 corresponding to the light shielding layer 152. In addition, the active pattern 130A is provided on the buffer layer 158 in the stage portion STP. The active pattern 130A may include a plurality of patterns spaced apart from each other along the first direction. The active layer 160 and the active pattern 130A may be provided of the same material and on the same layer.

The gate insulating layer 166 is provided on the active layer 160, and a first gate insulating pattern 166a is provided on the active pattern 130A. In addition, a second gate insulating pattern 166b is provided on the buffer layer 158 in the line portion LP.

The gate electrode 168, the gate 130G, and the signal line 131 are provided on the gate insulating layer 166, the first gate insulating pattern 166a, and the second gate insulating pattern 166b, respectively, as a second conductive layer. Accordingly, the gate electrode 168, the gate 130G, and the signal line 131 are provided of the same material and on the same layer.

Here, the gate insulating layer 166, the first gate insulating pattern 166a, and the second gate insulating pattern 166b are patterned to correspond to and to have substantially the same shapes as the gate electrode 168, the gate 130G, and the signal line 131, respectively. However, embodiments of the present disclosure are not limited thereto. Alternatively, the gate insulating layer 166, the first gate insulating pattern 166a, and the second gate insulating pattern 166b are connected to each other, so that a single insulating layer can be provided substantially over the entire surface of the substrate 150.

An interlayer insulating layer 169 is provided on the gate electrode 168, the gate 130G, and the signal line 131. The interlayer insulating layer 169 is disposed substantially over the entire surface of the substrate 150.

The source electrode 170, the drain electrode 172, the source 130S, the drain 130D, the connection line 132, and an auxiliary pattern 133 are provided on the interlayer insulating layer 169 as a third conductive layer. Accordingly, the source electrode 170, the drain electrode 172, the source 130S, the drain 130D, the connection line 132, and the auxiliary pattern 133 are provided of the same material and on the same layer.

The source electrode 170 and the drain electrode 172 are disposed to correspond to the active layer 160 and are in contact with respective end regions of the active layer 160 through contact holes of the interlayer insulating layer 169. In addition, the source electrode 170 is in contact with the light shielding layer 152 through a contact hole of the interlayer insulating layer 169 and the buffer layer 158.

The source 130S and the drain 130D are disposed to correspond to the active pattern 130A and are in contact with respective end regions of the active pattern 130A through contact holes of the interlayer insulating layer 169.

Each of the gate 130G, the source 130S, and the drain 130D may extend in the first direction, and the gate 130G may be disposed between the source 130S and the drain 130D along the second direction. Accordingly, a channel of the transistor TR is formed in the second direction. In this case, the channel of the transistor TR has a width of the first direction and a length of the second direction.

The connection line 132 and the auxiliary pattern 133 are disposed to correspond to the signal line 131 and spaced apart from each other. The connection line 132 and the auxiliary pattern 133 overlap the signal line 131.

A first end of the connection line 132 extends in the second direction and overlaps the signal line 131. In addition, a second end of the connection line 132 may be in direct or indirect contact with one of the gate 130G, the source 130S, and the drain 130D.

The auxiliary pattern 133 is in contact with the signal line 131 through a plurality of contact holes of the interlayer insulating layer 169. The connection line 132 is separated and insulated from the signal line 131 by the interlayer insulating layer 169.

Next, the passivation layer 176 is provided on the source electrode 170, the drain electrode 172, the source 130S, the drain 130D, the connection line 132, and the auxiliary pattern 133. The passivation layer 176 is disposed substantially over the entire surface of the substrate 150.

The overcoat layer 180 is provided on the passivation layer 176. The overcoat layer 180 is disposed substantially over the entire surface of the substrate 150.

The first electrode 182 and the connection pattern 134 are provided on the overcoat layer 180 as a fourth conductive layer. The first electrode 182 is disposed to correspond to the driving transistor Td and is in contact with the source electrode 170 through a contact hole of the overcoat layer 180 and the passivation layer 176. The connection pattern 134 is disposed to correspond to the signal line 131 and is in contact with the connection line 132 and the auxiliary pattern 133 through contact holes of the overcoat layer 180 and the passivation layer 176. In this case, a plurality of contact holes may be provided between the connection pattern 134 and the connection line 132 and between the connection pattern 134 and the auxiliary pattern 133.

Next, the bank layer 184, the emitting layer 186, and the second electrode 188 are sequentially provided on the first electrode 182, and the first encapsulating layer 190 and the second encapsulating layer 192 are sequentially provided on the second electrode 188.

As described above, in the organic light emitting diode display apparatus 110 according to the embodiment of the present disclosure, the stage STG of the stage portion STP is connected to the signal line 131 through the connection line 132 and the connection pattern 134. That is, the stage STG is connected to the connection line 132, and the connection pattern 134, which is provided of the same material and on the same layer as the first electrode 182, is in contact with the connection line 132 and the signal line 131. In this case, the connection line 132 may be connected to the gate 130G, the source 130S, or the drain 130D of the transistor TR of the stage STG.

Similarly, the stage STG of the stage portion STP is connected to the gate line GL through the connection line 132 and the connection pattern 134.

Accordingly, before forming the first electrode 182, the stage STG of the stage portion STP is electrically separated from the signal line 131 and the gate line GL. The stage STG is connected to each of the signal line 131 and the gate line GL through the connection pattern 134, which is formed together with the first electrode 182. Therefore, it is possible to protect the stage STG of the stage portion STP from the static electricity occurring during the manufacturing processes.

At this time, the auxiliary pattern 133 is provided between the signal line 131 and the connection pattern 133. The connection pattern 134 is connected to the signal line 131 through the auxiliary pattern 133. The auxiliary pattern 133 may be provided of the same material and on the same layer as the connection line 132.

The plurality of insulating layers (i.e., interlayer insulating layer 169, passivation layer 176, and overcoat layer 180) is disposed between the signal line 131 and the connection pattern 134. If the connection pattern 134 is in direct contact with the signal line 131, the contact holes may not be properly formed, or the connection pattern 134 may not be properly formed in the contact holes, so that there may be a high possibility that a contact failure may occur between the signal line 131 and the connection pattern 134. Accordingly, it is desirable that the auxiliary pattern 133 is further provided between the signal line 131 and the connection pattern 134, thereby improving the contact property between the signal line 131 and the connection pattern 134.

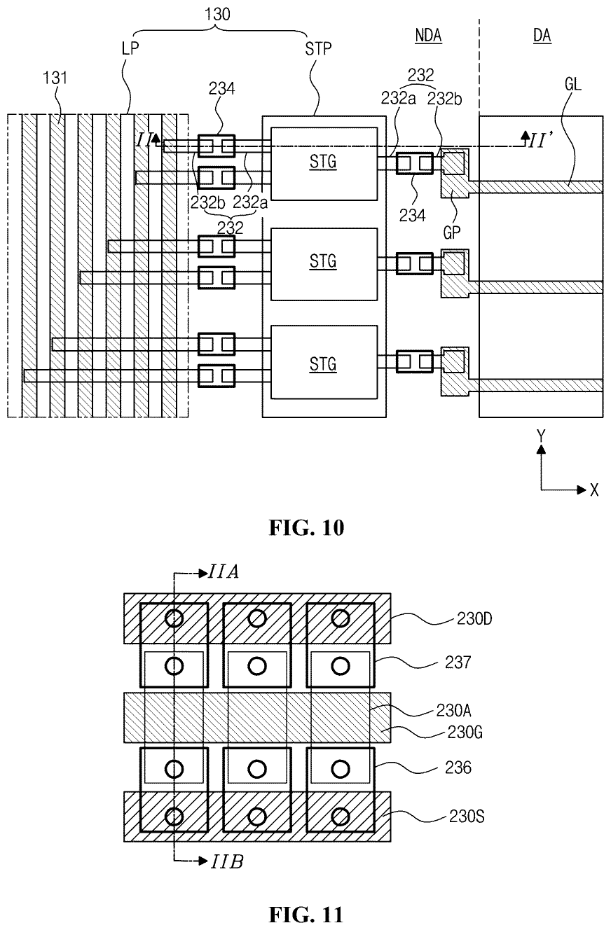

In the previous embodiment, the connection pattern 134 is provided right over the signal line 131 or the gate pad GP of the gate line GL. Alternatively, the connection pattern 134 may be provided to be spaced apart from the signal line 131 or the gate pad GP of the gate line GL. Another embodiment of the present disclosure having such a configuration will be described with reference to FIGS. 10 to 12.

FIG. 10 is a plan view schematically illustrating a display panel of an organic light emitting diode display apparatus according to another embodiment of the present disclosure and shows a gate driving unit and a display area. The organic light emitting diode display apparatus according to another embodiment of the present disclosure has substantially the same configuration as that of the previous embodiment, except for the connection line and the connection pattern. The same or similar parts as those of FIG. 5 will be designated by the same or similar references, and explanation for the same parts will be omitted or shortened.

In FIG. 10, the plurality of gate lines GL is provided in the display area DA and extends in the first direction, which is the X direction. The gate pad GP is provided at one end of each gate line GL, and the gate pad GP is disposed in the non-display area NDA.

The gate driving unit 130 is provided in the non-display area NDA, and the gate driving unit 130 includes the stage portion STP including the plurality of stages STG and the line portion LP including the plurality of signal lines 131. The stage portion STP is disposed between the line portion LP and the display area DA. Here, the plurality of signal lines 131 may extend in the second direction, which is the Y direction.

The stage portion STP may correspond to the stage circuit block Bsc of FIG. 2, and the line portion LP may correspond to the clock signal block Bel and the high-level voltage block Bhv of FIG. 2. The stages STG of the stage portion STP may include a plurality of transistors and a plurality of capacitors and output the gate signal. The signal lines 131 of the line portion LP may transmit a scan clock, a carry clock, a gate high-level voltage, a start signal, a reset signal, or a real time signal.

The transistor of the stage STG may have the same structure as that shown in FIG. 8 and FIG. 9. However, embodiments of the present disclosure are not limited thereto.

Each stage STG is electrically connected to at least one signal line 131 and at least one gate line GL. Here, the signal line 131 and the gate line GL may be provided of the same material and on the same layer.

Specifically, the stage STG is electrically connected to the signal line 131 and the gate line GL through a connection line 232 and a connection pattern 234, respectively. In this case, the connection line 232 may be electrically connected to the gate line GL through the gate pad GP.

The connection line 232 may extend in the first direction and may include a first line 232a and a second line 232b spaced apart from each other in the first direction. The first line 232a is connected to the stage STG, and the second line 232b overlaps the signal line 131 or the gate pad GP and is connected to the signal line 131 or the gate pad GP. The first line 232a may be directly connected to a gate layer or a source/drain layer provided in the stage STG.

The connection pattern 234 is disposed between the line portion LP and the stage portion STP or between the stage portion STP and the display area DA. The connection pattern 234 overlaps the first line 232a and the second line 232b and is connected to the first line 232a and the second line 232b.

The connection line 232 and the connection pattern 234 are formed of different materials and on different layers from each other. In addition, the connection line 232 and the connection pattern 234 may be disposed on different layers from the signal line 131 and the gate line GL.

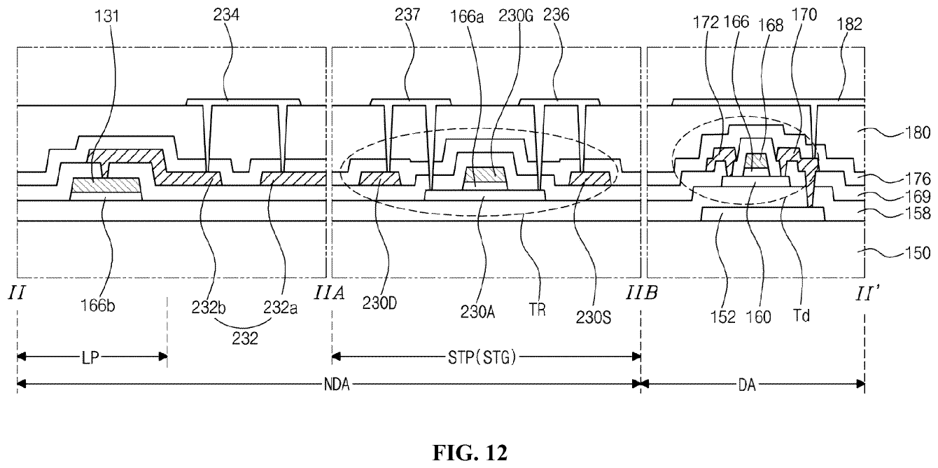

Hereinafter, plan and cross-sectional configurations of the display panel of FIG. 10 will be described in detail with reference to FIGS. 11 and 12.

FIG. 11 is a plan view schematically illustrating a transistor of a stage of FIG. 10, and FIG. 12 is a cross-sectional view corresponding to line II-II′ of FIG. 10. FIG. 12 also shows a cross-sectional configuration corresponding to line IIA-IIB of FIG. 11. Here, the transistor of the stage of FIGS. 11 and 12 may have a different structure from that of the embodiment of FIGS. 8 and 9.

In FIGS. 11 and 12, the light shielding layer 15, the driving transistor Td, the light emitting diode De are provided in the display area DA on the substrate 150. The transistor TR, the signal line 131, the connection line 232, and the connection pattern 234 are provided in the non-display area NDA on the substrate 150. The transistor TR is disposed in each stage STG of the stage portion STP, and the signal line 131 is disposed in the line portion LP.

Here, the driving transistor Td includes the gate electrode 168, the active layer 160, the source electrode 170, and the drain electrode 172, and the light emitting diode De includes the first electrode 182, the emitting layer 186, and the second electrode 188.

The transistor TR includes a gate 230G, an active pattern 230A, a source 230S, and a drain 230D.

Specifically, the light shielding layer 152 is provided on the substrate 150 as a first conductive layer, and the buffer layer 185 is provided on the light shielding layer 152. The buffer layer 158 is disposed substantially over an entire surface of the substrate 150.

The active layer 160 is provided on the buffer layer 158 corresponding to the light shielding layer 152. In addition, the active pattern 230A is provided on the buffer layer 158 in the stage portion STP. The active pattern 230A may include a plurality of patterns spaced apart from each other along the first direction. The active layer 160 and the active pattern 230A may be formed of the same material and on the same layer.

The gate insulating layer 166 is provided on the active layer 160, and the first gate insulating pattern 166a is provided on the active pattern 230A. In addition, the second gate insulating pattern 166b is provided on the buffer layer 158 in the line portion LP.

The gate electrode 168, the gate 230G, and the signal line 131 are provided on the gate insulating layer 166, the first gate insulating pattern 166a, and the second gate insulating pattern 166b, respectively, as a second conductive layer. Accordingly, the gate electrode 168, the gate 230G, and the signal line 131 are provided of the same material and on the same layer.

Here, the gate insulating layer 166, the first gate insulating pattern 166a, and the second gate insulating pattern 166b are patterned to correspond to and to have substantially the same shapes as the gate electrode 168, the gate 230G, and the signal line 131, respectively. However, embodiments of the present disclosure are not limited thereto. Alternatively, the gate insulating layer 166, the first gate insulating pattern 166a, and the second gate insulating pattern 166b are connected to each other, so that a single insulating layer can be provided substantially over the entire surface of the substrate 150.

The interlayer insulating layer 169 is provided on the gate electrode 168, the gate 230G, and the signal line 131. The interlayer insulating layer 169 is disposed substantially over the entire surface of the substrate 150.

The source electrode 170, the drain electrode 172, the source 230S, the drain 230D, and the connection line 232 are provided on the interlayer insulating layer 169 as a third conductive layer. Accordingly, the source electrode 170, the drain electrode 172, the source 230S, the drain 230D, and the connection line 232 are provided of the same material and on the same layer.

The source electrode 170 and the drain electrode 172 are disposed to correspond to the active layer 160 and are in contact with respective end regions of the active layer 160 through contact holes of the interlayer insulating layer 169. In addition, the source electrode 170 is in contact with the light shielding layer 152 through the contact hole of the interlayer insulating layer 169 and the buffer layer 158.

The source 230S and the drain 230D are disposed to correspond to the active pattern 230A. The source 230S and the drain 230D are spaced apart from the active pattern 230A.

Each of the gate 230G, the source 230S, and the drain 230D may extend in the first direction, and the gate 230G may be disposed between the source 230S and the drain 230D along the second direction. Accordingly, a channel of the transistor TR is formed in the second direction. In this case, the channel of the transistor TR has a width of the first direction and a length of the second direction.

The connection line 232 includes the first line 232a and the second line 232b, and the first line 232a and the second line 232b are spaced apart from each other. The first line 232a is connected to the stage STG. In this case, the first line 232a may be in direct or indirect contact with one of the gate 230G, the source 230S, and the drain 230D of the transistor TR. The second line 232b overlaps the signal line 131 and is in contact with the signal line 131 through a contact hole of the interlayer insulating layer 169.

Next, the passivation layer 176 is provided on the source electrode 170, the drain electrode 172, the source 230S, the drain 230D, and the connection line 232. The passivation layer 176 is disposed substantially over the entire surface of the substrate 150.

The overcoat layer 180 is provided on the passivation layer 176. The overcoat layer 180 is disposed substantially over the entire surface of the substrate 150.

The first electrode 182, the connection pattern 234, and first and second patterns 236 and 237 are provided on the overcoat layer 180 as a fourth conductive layer. The first electrode 182 is disposed to correspond to the driving transistor Td and is in contact with the source electrode 170 through the contact hole of the overcoat layer 180 and the passivation layer 176. The connection pattern 234 is disposed to correspond to the connection line 232 and overlap the first and second lines 232a and 232b. The connection pattern 234 is in contact with the first and second lines 232a and 232b through the contact holes of the overcoat layer 180 and the passivation layer 176.

The first and second patterns 236 and 237 are disposed to correspond to the active pattern 230A. The first pattern 236 is in contact with one end region of the active pattern 230A through a contact hole of the overcoat layer 180, the passivation layer 176, and the interlayer insulating layer 169 and is in contact with the source 230S through a contact hole of the overcoat layer 180 and the passivation layer 176. The second pattern 237 is in contact with the other end region of the active pattern 230A through a contact hole of the overcoat layer 180, the passivation layer 176, and the interlayer insulating layer 169 and is in contact with the drain 230D through a contact hole of the overcoat layer 180 and the passivation layer 176.

Next, the bank layer 184, the emitting layer 186, and the second electrode 188 are sequentially provided on the first electrode 182, and the first encapsulating layer 190 and the second encapsulating layer 192 are sequentially provided on the second electrode 188.

As described above, in the organic light emitting diode display apparatus according to another embodiment of the present disclosure, the stage STG of the stage portion STP is connected to the signal line 131 through the connection line 232 and the connection pattern 234. Specifically, the first line 232a of the connection line 232 contacting the stage STG and the second line 232b of the connection line 232 contacting the signal line 131 are connected to each other through the connection pattern 234, which is provided of the same material and on the same layer as the first electrode 182.

Similarly, the stage STG of the stage portion STP is connected to the gate line GL through the connection line 232 and the connection pattern 234.

Accordingly, before forming the first electrode 182, the stage STG of the stage portion STP is electrically separated from the signal line 131 and the gate line GL. The stage STG is connected to each of the signal line 131 and the gate line GL through the connection pattern 234, which is formed together with the first electrode 182. Therefore, it is possible to protect the stage STG of the stage portion STP from the static electricity occurring during the manufacturing processes.

Meanwhile, in the previous embodiments, it is described as an example that the gate electrode 168 is disposed on a different layer from the source electrode 170 and the drain electrode 172, the signal line 131 is disposed on the same layer as the gate electrode 168, and the connection line 132 and 232 is disposed on the same layer as the source and drain electrodes 170 and 172. However, embodiments of the present disclosure are not limited thereto.

Alternatively, in other embodiments, the gate electrode 168 may be provided of the same material and on the same layer as the source electrode 170 and the drain electrode 172. In this case, the signal line 131 may be provided of the same material and on the same layer as the light shielding layer 152, and the connection line 132 and 232 may be provided of the same material and on the same layer as the gate electrode 168, the source electrode 170, and the drain electrode 172.

In the present disclosure, the stage of the gate driving unit is connected to the signal line or the gate line through the connection pattern, which is provided of the same material and on the same layer as the lower electrode of the light emitting diode, so that the static electricity occurring during the manufacturing processes can be prevented from flowing into the stage of the gate driving unit.

Additionally, in the present disclosure, by preventing the stage of the gate driving unit from being damaged due to the static electricity, the repair process can be omitted, and thus the manufacturing processes and costs can be reduced.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a substrate including a display area having a subpixel and a non-display area surrounding the display area;
a driving transistor provided at the subpixel;
a light emitting diode provided at the subpixel and including a first electrode, an emitting layer, and a second electrode; and
a gate driving unit provided in the non-display area,
wherein the gate driving unit includes a line portion including at least one signal line and a stage portion including at least one stage,
wherein the stage is connected to the signal line or a gate line of the display area through a connection line and a connection pattern, and
wherein the connection pattern is provided of a same material and on a same layer as the first electrode.

2. The display apparatus of claim 1, wherein the connection line is disposed on a different layer from the signal line and overlaps the signal line.

3. The display apparatus of claim 1, wherein the connection line is disposed between the signal line and the connection pattern.

4. The display apparatus of claim 1, further comprising an auxiliary pattern between the signal line and the connection pattern, wherein the auxiliary pattern overlaps the signal line and is spaced apart from the connection line.

5. The display apparatus of claim 4, wherein the auxiliary pattern is in contact with the signal line, and the connection line is separated from the signal line.

6. The display apparatus of claim 4, wherein the auxiliary pattern is formed of a same material and on a same layer as the connection line.

7. The display apparatus of claim 1, wherein the connection line includes a first line and a second line spaced apart from each other, and
wherein the first line is connected to the stage, and the second line is connected to the signal line.

8. The display apparatus of claim 7, wherein the connection pattern overlaps and is in contact with the first line and the second line.

9. The display apparatus of claim 1, further comprising a light shieling layer between the substrate and the driving transistor,
wherein the driving transistor includes a gate electrode, an active layer, a source electrode, and a drain electrode,
wherein the signal line is formed of a same material and on a same layer as the gate electrode, and
wherein the connection line is formed of a same material and on a same layer as the source electrode and the drain electrode.

10. The display apparatus of claim 1, further comprising a light shieling layer between the substrate and the driving transistor,
wherein the driving transistor includes a gate electrode, an active layer, a source electrode, and a drain electrode,
wherein the signal line is formed of a same material and on a same layer as the light shielding layer, and
wherein the connection line is formed of a same material and on a same layer as the gate electrode, the source electrode, and the drain electrode.

11. The display apparatus of claim 1, wherein the stage includes at least one transistor,
wherein the transistor includes a gate, an active pattern, a source, and a drain, and
wherein the active pattern is connected to the source through a first pattern and connected to the drain through a second pattern.

12. The display apparatus of claim 11, wherein the first pattern and the second pattern are formed of a same material and on a same layer as the first electrode.

13. The display apparatus of claim 1, wherein the signal line transmits a scan clock, a carry clock, a gate high-level voltage, a start signal, a reset signal, or a real time signal.

14. The display apparatus of claim 1, wherein the subpixel includes:
a switching transistor switched according to a scan signal and connected to a data signal;
a storage capacitor connected to the switching transistor;
the driving transistor switched according to a voltage of a capacitor electrode of the storage capacitor and connected to a high-level voltage;
a reference transistor switched according to a sensing signal and connected to the storage capacitor, the driving transistor and a reference signal, and
the light emitting diode connected to the storage capacitor, the driving transistor, the reference transistor, and a low-level voltage.

15. The display apparatus of claim 14, wherein at least one of the switching transistor, the driving transistor, and the reference transistor is an oxide semiconductor thin film transistor.

16. The display apparatus of claim 14, wherein the gate driving unit includes a clock signal block, a high-level voltage block, a stage circuit block, and a low-level voltage block,
wherein the stage circuit block generates and transmits the scan signal to the switching transistor through the gate line and generates and transmits the sensing signal to the reference transistor through the gate line, and
wherein the line portion includes the clock signal block and the high-level voltage block, and the stage portion includes the stage circuit block.

17. The display apparatus of claim 1, further comprising:
a light shieling layer provided at the subpixel;
a buffer layer between the light shielding layer and the driving transistor;
an overcoat layer between the driving transistor and the light emitting diode; and
a passivation layer between the driving transistor and the overcoat layer.

18. The display apparatus of claim 17, wherein the driving transistor includes:
an active layer corresponding to the light shielding layer and disposed over the buffer layer;
a gate insulating layer and a gate electrode sequentially disposed over the active layer;
a source electrode connected to a first end region of the active layer and the light shielding layer; and
a drain electrode connected to a second end region of the active layer.

19. The display apparatus of claim 1, further comprising a first encapsulating layer and a second encapsulating layer sequentially disposed over the light emitting diode,
wherein the first encapsulating layer includes at least one of an inorganic insulating material and an organic insulating material, and
wherein the second encapsulating layer includes a metallic material or glass.
